(19) United States
(12) Patent Application Publication
(10) Pub. No.: US 2026/0242925 A1
(43) Pub. Date: Aug. 20, 2026

(54) COATING METHOD AND DEVICE

(71) Applicant: Bühler Alzenau GmbH, Alzenau (DE)

(72) Inventor: Michael MÜCKE, Wöllstadt (DE)

(21) Appl. No.: 19/643,347

(22) Filed: Apr. 9, 2026

Related U.S. Application Data
(62) Division of application No. 18/002,785, filed on Jun. 25, 2021, now Pat. No. 12,618,137.

(30) Foreign Application Priority Data
Jun. 26, 2020 (EP) 20182452.1

(51) Int. Cl. C23C 14/04; C23C 14/14; C23C 14/24; C23C 14/56

(52) U.S. Cl. CPC C23C 14/042; C23C 14/14; C23C 14/24; C23C 14/562

(57) ABSTRACT

A device for coating a flexible, dielectric substrate is disclosed. The device includes a coating roll for guiding the substrate and a charging device for improving adhesion of the substrate to the coating roll. A first coating source is configured to apply a first metal layer to the substrate while leaving at least one longitudinal free strip uncoated. A second coating source is configured to apply a second metal layer to the substrate after the first layer has been applied. The uncoated free strip preserves a dielectric surface on the partially coated substrate, which allows for effective charging and adhesion during subsequent coating steps. The device may also include a treatment device, such as a mask or an oil applicator, for treating portions of the substrate surface to prevent metal deposition and form the free strips.

### CROSS-REFERENCE TO RELATED APPLICATIONS

This application is a divisional of and claims priority pursuant to 35 U.S.C. § 120 to U.S. Application No. 18/002,785, filed December 21, 2022, which application is a U.S. national stage filing under 35 U.S.C. § 371 of International Patent Application No. PCT/EP2021/025236, filed June 25, 2021, which international application claims the benefit of and priority to European Application No. 20182452.1, filed June 26, 2020, which applications are each incorporated herein by reference in their entireties.

### FIELD

The present disclosure relates to a method and a device for coating strip-type flexible, dielectric substrates, in particular, for repeated coating of such substrates.

### BACKGROUND

In conventional roll-to-roll coating processes, particularly those involving vacuum deposition, significant heat is generated as material is applied to a moving substrate. To manage this heat and maintain high processing speeds, it is known to enhance the thermal contact between the substrate and a cooled coating roll. One conventional approach involves electrostatically charging the dielectric substrate before it contacts the roll, which can create a strong adhesive force that improves heat dissipation.

However, the effectiveness of such conventional charging methods depends on the substrate having dielectric properties. When a conductive layer, such as a metal layer, is applied to the substrate, the surface becomes electrically conductive. Consequently, for subsequent coating processes, such as applying additional layers or coating the opposite side of the substrate, these conventional charging techniques may no longer be effective. This can result in poor adhesion to the coating roll, inefficient cooling, and a necessary reduction in coating speed, thereby limiting the ability to efficiently manufacture products that require multiple or double-sided conductive layers.

Accordingly, there exists a need in the art for an improved device and method for coating flexible substrates that maintains the benefits of enhanced cooling and high process speeds for sequential or double-sided coating operations, even after a first conductive layer has been applied.

### SUMMARY

Aspects of the present disclosure are directed to a device for coating a flexible dielectric substrate. In an embodiment, the device comprises a coating roll to guide the substrate, a charging device to improve adhesion of the substrate to the roll, a first coating source, and a second coating source. The first coating source is configured to apply a first metal layer to the substrate while leaving at least one longitudinal free strip of the substrate uncoated. The second coating source is configured to apply a second metal layer to the substrate after the first metal layer has been applied.

A technical problem addressed by aspects of the disclosure is the challenge of performing multi-layer or double-sided coating on substrates at high rates. While electrostatic charging is an effective technique for ensuring strong adhesion and thermal contact between a dielectric substrate and a cooled coating roll, its benefits are lost after a first metal layer is applied, as the substrate surface becomes electrically conductive. This conductivity prevents effective subsequent charging, which can lead to poor cooling and reduced process speeds, thereby limiting the production of more complex coated products.

An object of an aspect of the disclosure is to overcome this limitation by providing a device configured to create one or more uncoated, longitudinal free strips during a first metal coating process. These free strips maintain the dielectric nature of the underlying substrate, thereby providing regions that can maintain a previously applied charge or receive a new charge in subsequent coating steps. This configuration allows for improved adhesion to the coating roll even after the substrate has been partially metallized, extending the benefits of enhanced cooling to second and subsequent coating layers.

In some embodiments, the device further comprises a treatment device positioned to treat portions of the substrate surface before coating to prevent metal deposition thereon and thereby form the free strips. The treatment device may comprise, for example, an apparatus for applying a vaporizable oil via an offset printing method, a physical mask for covering the portions, or nozzles for directing an air stream to blow away or suction metal vapor. An object of these embodiments is to provide a mechanism for avoiding the application of the metal layer in the desired free strips.

In another aspect, the device is configured for double-sided coating, wherein the second coating source is positioned to apply the second metal layer to a surface of the substrate opposite the first surface. An object of this aspect is to facilitate the production of components requiring metallization on both sides, such as battery electrodes. In such embodiments, the device may be configured to form corresponding free strips on both sides of the substrate to ensure adhesion is improved regardless of which side is being coated.

These and other objects, features, and advantages of the various aspects and embodiments of the present disclosure will become readily apparent upon a review of the following detailed description of the present disclosure, in view of the drawings and appended claims.

### BRIEF DESCRIPTION

Various embodiments are disclosed, by way of example only, with reference to the accompanying schematic drawings in which corresponding reference symbols indicate corresponding parts, in which:

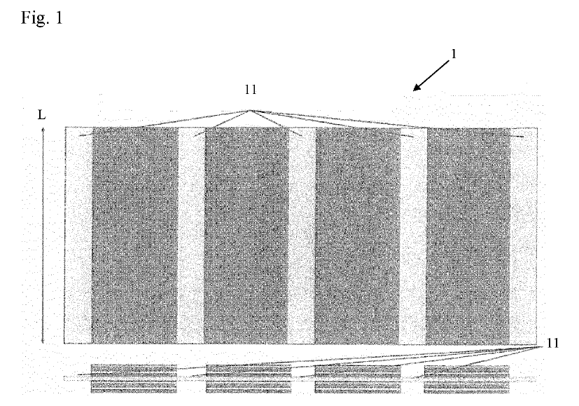

FIG. 1 a schematic plan view and a side view of a strip substrate provided with a metal layer by a method according to an aspect of the disclosure; and,

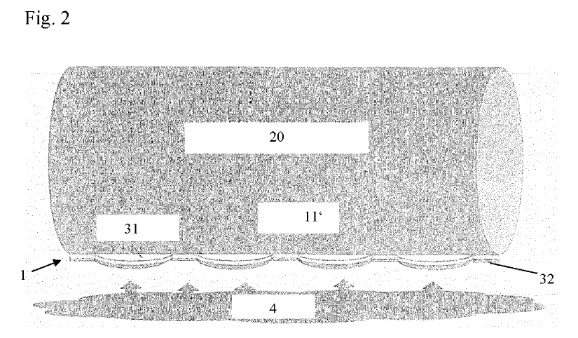

FIG. 2 a coating roll to illustrate a second coating process according to one embodiment of the present disclosure.

### DETAILED DESCRIPTION

Reference will now be made in detail to various embodiments, examples of which are illustrated in the accompanying drawings. While the subject matter will be described in conjunction with these embodiments, it will be understood that they are not intended to limit the scope of the claims to these embodiments. On the contrary, the disclosure is intended to cover alternatives, modifications, and equivalents. Furthermore, in the following detailed description, numerous specific details are set forth in order to provide a thorough understanding of the disclosed subject matter. However, it will be obvious to one of ordinary skill in the art that the disclosed subject matter may be practiced without these specific details. In other instances, well-known methods and procedures have not been described in detail so as not to unnecessarily obscure aspects of the present disclosure.

In the drawings, like reference numerals are used to identify similar elements. The drawings are not necessarily to scale, and relative feature sizes may be exaggerated for illustrative purposes.

The terminology used herein is for the purpose of describing particular aspects only and is not intended to be limiting. As used herein, the singular forms "a", "an", and "the" are intended to include the plural forms as well, unless the context clearly indicates otherwise.

It will be further understood that the term "comprise" and its derivatives, when used herein, specify the presence of stated features, integers, steps, operations, elements, and/or components, but do not preclude the presence or addition of one or more other features, integers, steps, operations, elements, components, and/or groups thereof. The transitional phrase "comprising" is interpreted as being open-ended, meaning "including, but not limited to." The term "and/or" includes any and all combinations of one or more of the associated listed items, and the term "or" is used in its inclusive sense ("and/or") unless the context clearly indicates a non-inclusive sense.

As used herein, the term "exemplary" is used in the sense of "serving as an example, instance, or illustration" and not in the sense of "ideal." The words "may," "can," "could," and "should" are used to indicate that a particular feature, structure, or characteristic is optional and not required, unless the context clearly indicates otherwise.

Relative terms such as "substantially," "around," and "approximately," when used in conjunction with a property or a value, are intended to describe a reasonable amount of deviation of the modified term such that the end result is not significantly changed, and may also define precisely the property or value, as would be understood by one of skill in the art.

The disclosure provides various specific dimensions, process parameters, and values. For instance, dimensions such as 3-4 cm strip widths, 1 cm free strips, and 600-700 mm substrate widths, as well as process values like coating rates of approximately 10 m/s and layer thicknesses from 50 nm to 1.5 µm, are mentioned. These values are provided as exemplary and are not intended to be limiting. The disclosure contemplates other suitable dimensions, values, rates, and ranges appropriate for a given application.

The disclosure describes the substrate as a "flexible, dielectric" film and the coating as a "metal layer," such as aluminum (Al). These materials are exemplary. The substrate may be formed from any suitable flexible dielectric material known in the art, and the metal layer may comprise any suitable metal, alloy, or conductive material known in the art. The described treatment and coating methods, such as offset printing, masking, vacuum vapor deposition, and sputtering, are also exemplary and not intended to be limiting.

The primary applications described herein relate to the production of battery electrodes, capacitors, and packaging films. These use cases are illustrative and not exhaustive. The disclosed device and method may be used in any other suitable application requiring the multi-layer or double-sided coating of flexible substrates.

The disclosure describes the use of an "air stream to blow the metal vapor" and "suctioning the metal vapor." This involves the controlled movement of a gas or vapor, which may be generated by any suitable means known in the art, such as nozzles, pumps, or blowers, configured to create a pressure differential that directs the flow of the gaseous medium.

During coating, in particular in vacuum coating processes for coating film webs in the production of electronic components, such as, for example, when applying aluminum (Al) layers during battery production, or also in the packaging industry, the film to be coated (the substrate) is guided over rolls and the actual coating is carried out when the film is running over a coating roll. For example, the coating can be applied to the substrate by vapor deposition methods or sputtering methods.

Thus, in particular in the production of packaging films, but also of capacitors or electrodes in battery production, thicker metal layers, in particular Al layers, are increasingly required on comparatively thick substrates. Accordingly, the coating times should not increase substantially, even in the case of these thicker layers. For example, with previous methods, it is only possible to achieve coating rates on the web substrate of at most approximately 10 m/s with a layer thickness of 50 nm Al. However, particularly in battery production, there is now already a need for layer thicknesses of 500 nm to even 1.5 µm Al on films with a thickness of only 8 µm, for example in the production of current collectors. With existing vacuum coating methods, this is hardly achievable. The high coating rates increase the heat of condensation on the substrate, thereby increasing the heat input to the substrate, which must be dissipated during the coating process. Therefore, methods are required which allow an increase in the cooling possibilities of the coating roll.

By charging the substrate before coating, for example by charging the substrate with an electron beam on the side facing away from the roll, the adhesion of the substrate on the coating roll is improved by electromagnetic force. The heat of condensation produced during the coating process can thus be released better over the roll.

In dielectric substrates, this is achieved successfully for a first coating process. However, it is often necessary, particularly in the case of the aforementioned application fields, to apply two or more metal layers to the substrate and/or to provide both sides of the substrate with a metal layer. An example of this can be the production of a cathode/anode pair. However, if a metal layer is applied to the substrate, the substrate has lost its dielectric nature and it is no longer possible to apply charge to the substrate.

According to the present disclosure, in order to also allow the adhesion of already metal-coated substrates on the coating roll by means of the charging device already used for the first coating process to also be able to be used for a further coating, at least one free strip is left free during coating with the metal layer in the longitudinal direction of the substrate. The metal coating is therefore not applied over the entire width of the substrate, but along at least one strip, preferably at least two or more strips, so that a region, which can receive the previously applied charge and/or to which charge can be applied in a further charge process, remains on the substrate. The adhesion on the coating roll can thus be improved at least in the free strips and thus the heat transfer to the roll can be ensured.

A correspondingly coated substrate 1 is shown schematically in FIG. 1 in a plan view and a side view. Along the longitudinal direction L of the substrate 1 to be coated, which can be provided in the form of a web with a length of up to several kilometers, strips 12 are provided with the coating, while strips 11 lying therebetween are kept free (free strips 11). The strips 11 or regions remaining free must be wide enough, on the one hand, to ensure sufficient adhesion of the partially metal-coated substrate 1; on the other hand, the width of the strips 11 should be selected to be as narrow as possible since the regions which remain free are not available for the production of the desired product later.

In order to avoid coating the substrate in the desired regions, the corresponding regions can be treated before coating. For example, an oil layer can be applied before the coating process in the region of the strips 11 that are not to be coated. This can preferably be carried out by means of an offset printing process. The use of an oil evaporation process, for example in the form of a strip oil evaporator, is also possible. In general, the use of oil is preferred since oil (or other suitable hydrocarbons) evaporates after a certain time in a vacuum, without damaging the substrate. Such substances evaporate during the subsequent coating in a vacuum and/or by heating the boundary layer during the coating process.

At the points at which the oil layer was applied, the substrate cannot be permanently metallized, and previously applied charges are maintained in these regions. In a subsequent coating process, these regions keep the substrate on the coating roll, despite the metal coating having been carried out in the other regions.

Other possibilities for preventing a metal coating locally on the substrate 1 are, for example, covering the corresponding regions by means of masking or applying a protective medium or the targeted action of an air flow for blowing or suctioning the metal vapor. Further, an already applied metal layer can also be vaporized specifically in situ in the corresponding regions of the strips 11 which are to be kept free, for example by the action of a local heat source, such as an IR laser. In addition, regions of highly reduced conductivity, in which the metal is applied reactively dielectrically in the region of the free strips 11, can be created prior to the coating in the corresponding strips 11.

The method according to the present disclosure can also be carried out several times in succession, wherein, after local processing to prevent the coating and subsequent coating in each case the substrate in turn, preferably in the same regions as in the first process, local regions are provided in which the coating is to be avoided, and subsequently the substrate is coated again. Thus, not only can the coating itself be effected several times in succession, but also the intermediate treatment steps of the regions not provided for the coating, such as, for example, the oil application by means of a strip oil evaporator.

Furthermore, the coating device for coating both the front and the rear side of a substrate in one working step can also be a further device for applying a metal layer, i.e., in particular a second coating roll, and optionally also a second device for treating the substrate also on the rear side to prevent a coating in the regions that are to be kept free.

For example, in the case of a substrate which is approximately 20 cm wide, four strips, each approximately 3-4 cm and each separated from strips remaining free of approximately 1 cm, can be applied. Also possible is the use of substrates which, for example, are 600 to 700 mm wide and 1.3 to 1.7 m in length. This can be used, for example, in the production of batteries, which are intended to be a certain size, for example approximately equal to A4 or A5 size, wherein the width of the strips can then be adapted accordingly.

Preferably, free strips 11 remain in the longitudinal direction of the substrate 1 at the two edges. Preferably, the strip pattern is formed symmetrically on the substrate. The substrate can also be treated from both sides such that the same regions of coating remain free on the front and rear sides. This is particularly preferred in cases where a metal coating is to be applied on both sides of the substrate 1. This results in regions which, despite the substrate 1 being turned for dual-sided coating or multiple coatings, are always kept free of metal coating on both sides. Despite being turned, these regions repeatedly increase the adhesion and continually trap air pockets, which maintain optimal cooling, which will now be explained in more detail with reference to FIG. 2.

FIG. 2 schematically shows a coating roll 20 over which a substrate 1 already coated once with a metal layer in a first coating process according to the present disclosure is guided. In the strip-type regions in which the metal layer is applied, the effect of the adhesion of the substrate 1 on the coating roll 20 is no longer provided by the charge already applied before the first coating or also newly applied after the first coating. Instead, air pockets 31 are formed in these regions between the roll 20 and the substrate 1. As described above, the air pockets 31 thus formed support the cooling of the substrate 1. In these regions, a gaseous medium for increasing the effect of a gas pocket can be introduced by means of a suitable method.

An oil film 32 which prevents coating of the substrate in these regions 11' has been applied in the other regions 11' of the substrate 1. There, the substrate 1 adheres to the roll 20, so that the air pockets/gas pockets 31 can be formed in the intermediate regions in order to ensure cooling and to ensure an optimal coating from the metal vapor 4 provided in the roll environment.

In addition to the method, the present disclosure therefore also provides a corresponding device for coating substrates using a device for charging the substrate, in particular by means of an electron beam, a device for treating the substrate to ensure that the desired free strips are not coated, for example a device for local application of a thin oil film, and finally a device for coating the substrate on a surface, in particular with a coating roll, for example a vacuum vapor deposition device. After the first coating has been carried out, the coating device, and optionally also the device for charging and/or treating, can then be used a further time making use of the advantages of the incomplete metal coating for a second and optionally further coatings on the same or also the opposite side, or, as already noted above, in each case second devices can be provided in order to apply a first and second coating in one process step, in particular on the front and rear sides of the substrate.

### EXAMPLES

The following provides a detailed description of certain exemplary embodiments of the present disclosure. It is to be understood that these embodiments are provided for illustrative purposes and are not to be construed as limiting the scope of the disclosure in any way.

In some aspects, a device for coating a strip-type, flexible, dielectric substrate is disclosed. The device may comprise a coating roll over which the substrate is guided in a longitudinal direction during a coating process. A charging device can be included and configured to charge the substrate to improve its adhesion to the coating roll. The device may further comprise a first coating source configured to apply a first metal layer to the substrate.

In these aspects, the device is configured such that, in the longitudinal direction of the substrate, at least one free strip remains which is not coated with the metal layer. A second coating source may also be provided for coating the substrate with a second metal layer after the first metal layer has been applied.

In some embodiments, the device may further comprise a treatment device for treating portions of the surface of the substrate on which the free strips are to remain, such that the application of the metal layer in those free strips is avoided. This treatment device may, for example, comprise an offset printing apparatus configured to apply an oil, a physical mask to cover the portions, an air nozzle to blow metal vapor away, or a suction nozzle to suction metal vapor.

In further embodiments, the second coating source may be configured to apply the second metal layer on an opposite surface of the substrate. For such double-sided coating applications, a second treatment device may be included to treat portions of the opposite surface, where the treated portions on the opposite surface may correspond to the free strips on the first surface.

Furthermore, in any of the foregoing embodiments, a re-charging device may be positioned to charge the substrate after the first metal layer has been applied but before the second metal layer is applied. The first coating source can be configured to leave at least two longitudinal free strips uncoated, for instance, at the opposite longitudinal edges of the substrate.

It is to be understood that any of the features described, such as the specific types of treatment devices or the placement of the second coating source for opposite-side coating, may be combined in various ways in any of the disclosed embodiments. The charging device may, in some aspects, be an electron beam charger, and the coating sources may comprise a vacuum vapor deposition source.

It will be appreciated that the embodiments of the present disclosure are merely exemplary and that various features and functions, or alternatives thereof, may be desirably combined into many other different systems or applications. Thusly, various alternatives, combinations, and omissions of specific components, as well as presently unforeseen or unanticipated modifications, variations, or improvements therein may be subsequently made by those skilled in the art, and are all intended to be encompassed by the appended claims.

What is claimed is:

1. A device for coating a flexible dielectric substrate, the device comprising:
a coating roll configured to guide the substrate in a longitudinal direction;
a charging device positioned to charge the substrate to improve adhesion of the substrate to the coating roll;
a first coating source configured to apply a first metal layer to a first surface of the substrate while the substrate is on the coating roll, wherein the first coating source is configured to leave at least one longitudinal free strip on the first surface uncoated by the first metal layer; and,
a second coating source configured to apply a second metal layer to the substrate after the first metal layer has been applied.

2. The device according to claim 1, further comprising a treatment device positioned upstream of the first coating source, the treatment device configured to treat a portion of the first surface of the substrate corresponding to the at least one longitudinal free strip to prevent application of the first metal layer thereon.

3. The device according to claim 2, wherein the treatment device comprises an offset printing apparatus configured to apply an oil to the portion of the first surface of the substrate.

4. The device according to claim 2, wherein the treatment device comprises a mask configured to cover the portion of the first surface of the substrate.

5. The device according to claim 2, wherein the treatment device comprises at least one of an air nozzle configured to direct an air flow to blow metal vapor away from the portion of the first surface of the substrate or a suction nozzle configured to suction metal vapor away from the portion of the first surface of the substrate.

6. The device according to claim 1, wherein the second coating source is positioned to apply the second metal layer to a second surface of the substrate, the second surface being opposite the first surface.

7. The device according to claim 6, further comprising a second treatment device positioned upstream of the second coating source, the second treatment device configured to treat a portion of the second surface of the substrate to prevent application of the second metal layer thereon, wherein the portion of the second surface corresponds to the at least one longitudinal free strip on the first surface.

8. The device according to claim 1, further comprising a re-charging device positioned between the first coating source and the second coating source, the re-charging device configured to charge the substrate after the first metal layer has been applied.

9. The device according to claim 1, wherein the first coating source is configured to leave at least two longitudinal free strips uncoated, wherein the at least two longitudinal free strips are located at opposite longitudinal edges of the substrate.

10. The device according to claim 1, wherein the charging device comprises an electron beam charger.

11. The device according to claim 1, wherein at least one of the first coating source or the second coating source comprises a vacuum vapor deposition source.

12. A device for coating a strip-type, flexible, dielectric substrate with a metal layer on a coating roll over which the substrate is guided in the longitudinal direction (L) of the substrate during the coating process, wherein the device comprises:
a first device for charging the substrate to improve adhesion of the substrate on the coating roll during the coating process;
a second device for coating the substrate with a first metal layer, wherein the second device is configured such that, in the longitudinal direction (L) of the substrate, at least one free strip remains which is not coated with the metal layer; and,
a third device for coating the coated substrate with a second metal layer.

13. The device according to claim 12, further comprising a fourth device for applying a second metal layer on an opposite surface of the substrate.

14. The device according to claim 12, further comprising a fifth device for treating the portions of the surface of the substrate to be coated, on which portions the free strips are to remain, in such a way that the application of the metal layer in the free strips is avoided.
